(19) United States
(12) Patent Application Publication
(10) Pub. No.: US 2010/0157621 A1
(43) Pub. Date: Jun. 24, 2010

(54) LIGHT EMITTING DEVICE WITH LED OPTICAL FIBER COUPLING

(75) Inventor: JEN-TSORNG CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/541,643

(22) Filed: Aug. 14, 2009

(30) Foreign Application Priority Data
Dec. 19, 2008 (CN) 200810306399.0

(51) Int. Cl. H01L 33/00

(52) U.S. Cl. 362/555; 362/554

(57) ABSTRACT

An exemplary light emitting device includes light emitting diodes optical fibers, and a light guide body. Each optical fiber includes a light input end and a light output end. Each light emitting diode is optically coupled to the light input end of a corresponding optical fiber. The light guide body includes a light incident surface and a light emitting surface. The light output end of each optical fiber is optically coupled to the light guide body at the light incident surface such that light output from the light output end is capable of emitting from the light guide body through the light emitting surface.

### BACKGROUND

1. Technical Field

The present disclosure relates to a light emitting device utilizing optical fiber light coupling between light emitting diodes and an output of a light guide body.

2. Description of Related Art

Various kinds of electronic equipment, such as cell phones and flat panel displays, are now in widespread use. In order to attract consumers, colorful light sources are arranged in the shells of many items of electronic equipment. However, it can be difficult to efficiently provide these light sources. This is due to factors such as the complex spatial arrangement of the light sources, and the required electrical connection between the light sources and a circuit board.

Therefore, a new light emitting device is desired to overcome the above-mentioned problems.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic plan view of a light emitting device including a light source module, according to a first embodiment of the present disclosure.

FIG. 2 is a cross-sectional view of the light source module of the light emitting device of FIG. 1.

FIG. 3 is a cross-sectional view of a light source module of a light emitting device according to a second embodiment of the present disclosure.

### DETAILED DESCRIPTION

Embodiments will now be described in detail below with reference to the drawings.

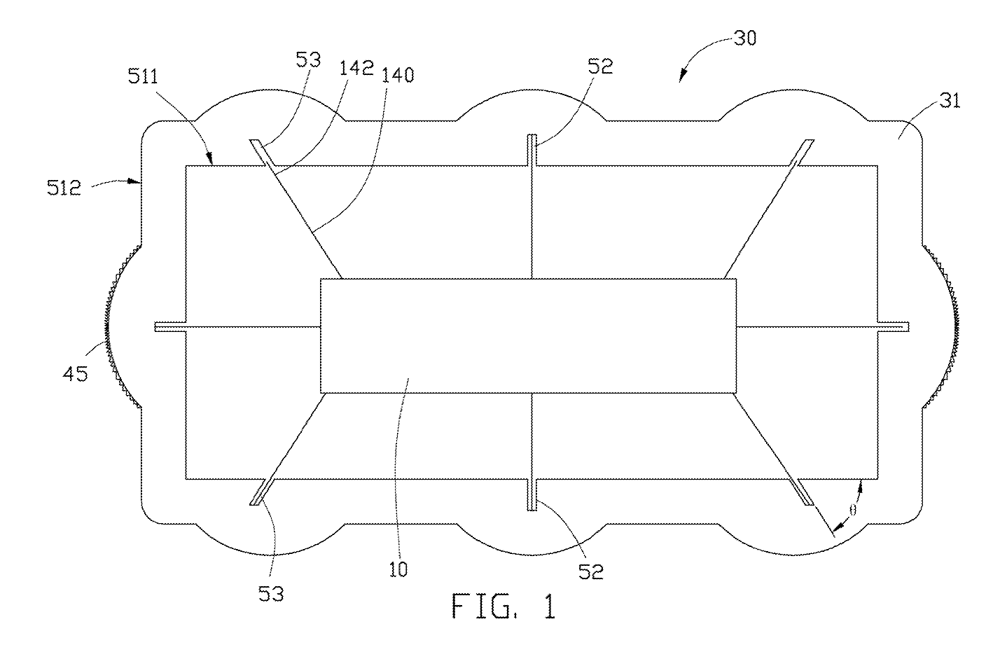

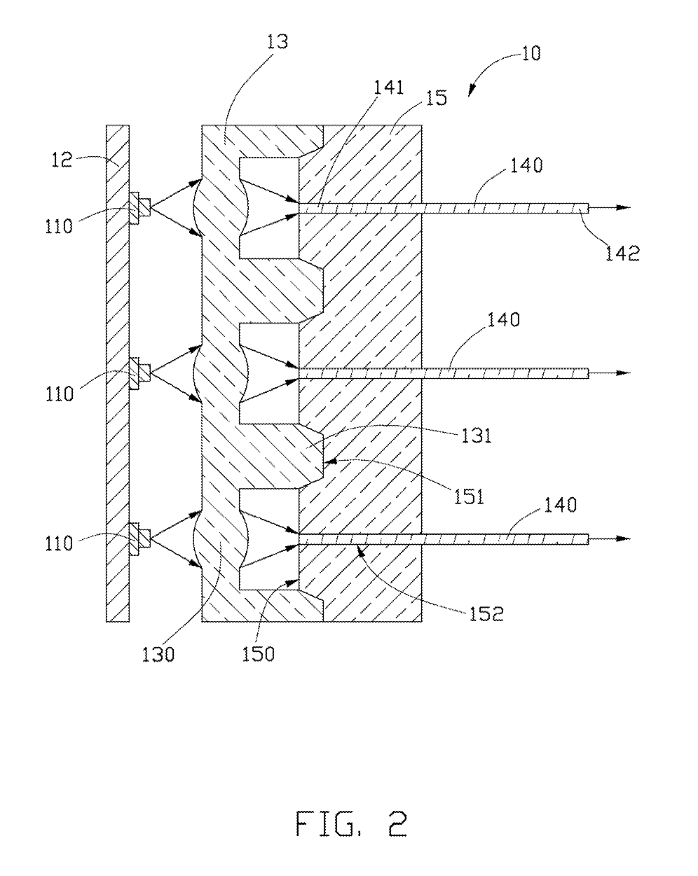

Referring to FIGS. 1-2, a light emitting device 30 according to a first embodiment of the present disclosure is shown. The light emitting device 30 includes a light source module 10, and a light guide body 31. In the illustrated embodiment, the light source module 10 is received in the light guide body 31.

The light source module 10 includes a circuit board 12, a plurality of light emitting diodes (LEDs) 110, a converging lens array 13, a plurality of optical fibers 140, and a holder 15 for keeping the optical fibers 140 in place. The LEDs 110 are electrically mounted on the circuit board 12. The circuit board 12 can include a drive circuit, a control circuit, and a sequential circuit so that the LEDs 110 can emit light in a predetermined sequence. The converging lens array 13 includes a plurality of interconnected converging lenses 130 and a plurality of supporting rods 131. Each converging lens 130 spatially corresponds to a respective LED 110. The holder 15 includes a side surface 150, a plurality of recesses 151 defined in the side surface 150, and a plurality of trenches 152 defined in the side surface 150 and spanning through an entire thickness of the holder 15. The holder 15 can be made of light pervious material. Each supporting rod 131 of the lens array 13 is inserted into a corresponding recess 151 of the holder 15 such that the lens array 13 is firmly coupled to the holder 15. Each optical fiber 140 is inserted into a respective trench 152 of the holder 15. Each optical fiber 140 includes a light input end 141 and a light output end 142. Each light input end 141 is optically coupled to a corresponding LED 110. Each light output end 142 is optically coupled to the light guide body 31.

In the present embodiment, the light guide body 31 is a substantially rectangular four-sided frame. The light guide body 31 includes an inner light incident surface 511 and an outer light emitting surface 512. In particular, the light incident surface 511 is an inner peripheral surface of the light guide body 31 (i.e., a substantially four-sided surface). The light emitting surface 512 is an outer peripheral surface of the light guide body 31 (i.e., a substantially four-sided surface). The light incident surface 511 defines a plurality of first recesses 52 and second recesses 53 therein. Each first recess 52 is oblong, and extends in a direction substantially perpendicular to the light incident surface 511. Each second recess 53 is oblong, and extends in a direction oblique to the light incident surface 511. An included angle θ formed between the light incident surface 511 and each second recess 53 is in an approximate range from 20 degrees to 45 degrees.

In one embodiment, a height (or thickness) of the four-sided frame of the light guide body 31 is much less than each of a length and a width of the four-sided frame. That is, the four-sided frame is a low-profile frame. In such case, the light source module 10 may be aligned substantially parallel with the low profile of the four-sided frame. In other embodiments, the light source module 10 may be oriented otherwise relative to the four-sided frame of the light guide body 31.

The light output end 142 of each optical fiber 140 is inserted into a respective first or second recess 52, 53 of the light guide body 31. To help achieve uniform illumination, the light emitting surface 512 includes a plurality of microstructures 45 formed thereat. In the illustrated embodiment, two sets of the microstructures 45 are formed at two curved protrusions at opposite ends of the light guide body 31, respectively. It is to be understood that in further or alternative embodiments, a set of microstructures 45 can be formed at each of any one or more other curved protrusions which are located at opposite long sides of the light guide body 31. The microstructures 45 can be micro-protrusions or micro-recesses.

The light guide body 31 can be made of light pervious material, such as polymethyl methacrylate (PMMA) or polycarbonate (PC). The light guide body 31 can, for example, function as a shell of a display device.

In use, a given LED 110 emits light towards a corresponding converging lens 130, and the light is converged by the converging lens 130 and coupled to the light input end 141 of a corresponding optical fiber 140. Subsequently, the light is transmitted within the optical fiber 140 and is outputted from the light output end 142 of the optical fiber 140 to the light guide body 31. As a result, the light emitting device 30 emits light through the light emitting surface 512.

Since the light emitted by the LEDs 110 is coupled to the light guide body 31 via the optical fibers 140, loss of light is reduced, thus improving the efficiency of use of the LEDs 110. Furthermore, since the optical fibers 140 are flexible, the light of the light source module 10 can be conveniently directed to any desired positions of the light guide body 31. It is to be understood that the LEDs 110 can emit light of different colors, depending on the needs of practical applications.

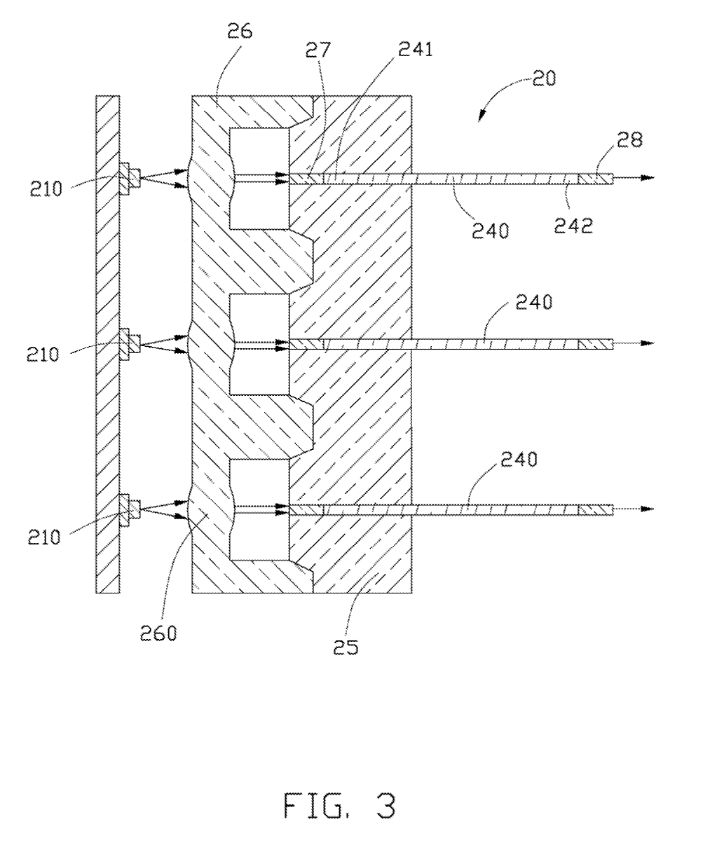

Referring to FIG. 3, a light source module 20 according to a second embodiment of the present disclosure is shown. The light source module 20 is similar to the light source module 10 of FIG. 2, except that the converging lens array 13 is replaced by a collimating lens array 26, and a first converging lens 27 and a second converging lens 28 are respectively optically coupled to a light input end 241 and a light output end 242 of each optical fiber 240. The collimating lens array 26 includes a plurality of collimating lenses 260. Each collimating lens 260 is arranged between a corresponding LED 210 and a corresponding first converging lens 27. The collimating lens 260 is configured (i.e. structured and/or arranged) for collimating light emitted by the LED 210. Each first converging lens 27 is received in a holder 25, and is in contact with the light input end 241 of the corresponding optical fiber 240. Each second converging lens 28 is in contact with the light output end 242 of the corresponding optical fiber 240. The first and second converging lenses 27, 28 can be gradient index (GRIN) lenses.

While certain embodiments have been described and exemplified above, various other embodiments from the foregoing disclosure will be apparent to those skilled in the art. The present invention is not limited to the particular embodiments described and exemplified but is capable of considerable variation and modification without departure from the scope and spirit of the appended claims.

What is claimed is:

1. A light emitting device comprising:
a plurality of light emitting diodes;
a plurality of optical fibers, each optical fiber comprising a light input end and a light output end, each light emitting diode being optically coupled to the light input end of a corresponding optical fiber; and
a light guide body comprising a light incident surface and a light emitting surface, the light output end of each optical fiber being optically coupled to the light guide body at the light incident surface such that light output from the light output end is capable of emitting from the light guide body through the light emitting surface.

2. The light emitting device of claim 1, wherein the light incident surface defines a plurality of recesses therein, and the light output end of each optical fiber is received in a corresponding recess.

3. The light emitting device of claim 2, wherein each of the recesses is oblong, and an included angle formed between the light incident surface and each recess is selected from the group consisting of in the range from 20 degrees to 45 degrees, and approximately 90 degrees.

4. The light emitting device of claim 1, wherein the light guide body further comprises a plurality of microstructures formed at the light emitting surface.

5. The light emitting device of claim 4, wherein the microstructures are selected from the group consisting of recesses and protrusions.

6. The light emitting device of claim 1, further comprising a plurality of converging lenses, wherein each light emitting diode is optically coupled to an input side of a corresponding converging lens, and an output side of the corresponding converging lens is optically coupled to the light input end of the corresponding optical fiber.

7. The light emitting device of claim 6, further comprising a plurality of collimating lenses, wherein each light emitting diode is optically coupled to an input side of a corresponding collimating lens, and an output side of the corresponding collimating lens is optically coupled to the corresponding converging lens.

8. The light emitting device of claim 1, further comprising a plurality of collimating lenses, wherein each light emitting diode is optically coupled to an input side of a corresponding collimating lens, and an output side of the corresponding collimating lens is optically coupled to the light input end of the corresponding optical fiber.

9. The light emitting device of claim 1, further comprising a holder retaining the optical fibers in position.

10. The light emitting device of claim 1, wherein the light guide body is generally frame-shaped, the light emitting diodes are received in a space defined by the frame-shaped light guide body, the light incident surface is an inner peripheral surface of the light guide body, and the light emitting surface is an outer peripheral surface of the light guide body.

11. A light emitting device comprising:
a plurality of light emitting diodes;
a plurality of optical fibers, each optical fiber comprising a light input end and a light output end, each light input end being optically coupled to a corresponding light emitting diode; and
a frame-shaped light guide body comprising an inner peripheral light incident surface and an outer peripheral light emitting surface, each light output end being optically coupled to the light guide body at the light incident surface such that light emitted by the corresponding light emitting diode is finally emitted from the light emitting surface.

12. The light emitting device of claim 11, wherein the light incident surface defines a plurality of recesses therein, and the light output end of each optical fiber is received in a corresponding recess.

13. The light emitting device of claim 12, wherein each of the recesses is oblong, and an included angle formed between the light incident surface and each recess is selected from the group consisting of in the range from 20 degrees to 45 degrees, and approximately 90 degrees.

14. The light emitting device of claim 11, wherein the light guide body further comprises a plurality of microstructures formed at the light emitting surface.

15. The light emitting device of claim 14, wherein the microstructures are selected from the group consisting of recesses and protrusions.

16. The light emitting device of claim 11, further comprising a plurality of converging lenses, wherein each light emitting diode is optically coupled to an input side of a corresponding converging lens, and an output side of the corresponding converging lens is optically coupled to the light input end of the corresponding optical fiber.

17. The light emitting device of claim 16, further comprising a plurality of collimating lenses, wherein each light emitting diode is optically coupled to an input side of a corresponding collimating lens, and an output side of the corresponding collimating lens is optically coupled to the corresponding converging lens.

18. The light emitting device of claim 11, further comprising a plurality of collimating lenses, wherein each light emitting diode is optically coupled to an input side of a corresponding collimating lens, and an output side of the corresponding collimating lens is optically coupled to the light input end of the corresponding optical fiber.

19. The light emitting device of claim 11, further comprising a holder retaining the optical fibers in position.

20. The light emitting device of claim 11, wherein the light guide body defines a pace therein, the light emitting diodes are received in the space, the light incident surface is an inner peripheral surface of the light guide body, and the light emitting surface is an outer peripheral surface of the light guide body.
